(19) United States
(12) Patent Application Publication
(10) Pub. No.: US 2021/0404068 A1
(43) Pub. Date: Dec. 30, 2021

(54) ETCHING SOLUTION, ANNEXING AGENT, AND MANUFACTURING METHOD OF METAL WIRING

(71) Applicant: TCL CHINA STAR OPTOELECTRONICS TECHNOLOGY CO., LTD., Shenzhen, Guangdong (CN)

(72) Inventors: Haoxu WU, Shenzhen, Guangdong (CN); Yuehong ZHANG, Shenzhen, Guangdong (CN)

(21) Appl. No.: 16/652,286

(22) PCT Filed: Mar. 17, 2020
(86) PCT No.: PCT/CN2020/079565

§ 371 Date: Mar. 30, 2020

(30) Foreign Application Priority Data
Feb. 13, 2020 (CN) 202010090863.8

(51) Int. Cl. C23F 1/26; C23F 1/18; C23F 1/02

(52) U.S. Cl. CPC C23F 1/26; C23F 1/02; C23F 1/18

(57) ABSTRACT

An etching solution, an annexing agent, and a manufacturing method of a metal wiring are disclosed. A main ingredient of the etching solution includes hydrogen peroxide accounting for 5% to 30% of a total weight of the etching solution, a hydrogen peroxide stabilizer accounting for 0.1% to 5% of the total weight of the etching solution, a chelant accounting for 5% to 25% of the total weight of the etching solution, a surface active agent accounting for 0.1% to 1% of the total weight of the etching solution, an inorganic acid oxidant accounting for 0.1% to 5% of the total weight of the etching solution, and a remainder of the etching solution is deionized water. The annexing agent is added to the etching solution when the etching solution is used repeatedly.

### CROSS REFERENCE TO RELATED APPLICATIONS

This is a U.S. National Phase Application under 35 U.S.C. § 371 of International Patent Application No. PCT/CN2020/079565, filed on Mar. 17, 2020, and claims priority of Chinese patent Application No. CN202010090863.8 filed on Feb. 13, 2020 with the National Intellectual Property Administration, titled “ETCHING SOLUTION, ANNEXING AGENT, AND MANUFACTURING METHOD OF METAL WIRING”, which is incorporated by reference in the present application in its entirety,

### FIELD OF INVENTION

The present disclosure relates to the field of etching solution technologies, and particularly relates to an etching solution, an annexing agent, and a manufacturing method of a metal wiring.

### BACKGROUND OF INVENTION

Etching is a technique using chemical reactions or physical impact to remove materials, and the technique can be divided into wet etching and dry etching. Wherein, wet etching is using chemical reagent to achieve a purpose of etching through chemical reactions. Effects of etching can directly influence accuracy and precision of thin and high-density wires.

Aluminum or aluminum alloy is used in metal wiring of liquid crystal displays (LCDs) in the past. However, with liquid crystal displays become bigger and having higher resolution, problems such as signal delay easily occur as a result of large resistivity of aluminum or aluminum alloy materials, thereby affecting display effects. Meanwhile, copper materials have lower resistivity, and can satisfy wiring requirements of large-sized panels. Molybdenum has high adhesion to substrates such as glass, etc., is difficult to diffuse into silicon semiconductor films, and also has barrier properties. Therefore, copper/molybdenum layers have been used as gate electrodes, source electrodes, and drain electrodes of thin film transistors in the liquid crystal displays, as well as metal layer structures such as gate lines and data lines connected to the thin film transistors. Furthermore, developments of relative etching solutions appear to be quite important.

In order to improve etching rates, current etching solutions of copper/molybdenum film layers with hydrogen peroxide radicals generally contain fluorides. However, fluorides are neither environmentally friendly nor favorable to operators' health. Furthermore, fluorides' corrosion ability is strong, and often causes corrosion on glass substrates. Moreover, waste water of etching production lines contain a large amount of fluorides that also poses a threat to the environment, which greatly increases processing cost of liquid waste.

Based on the above, improvement to the current fluoride-containing copper/molybdenum film layer etching solutions is necessary.

### SUMMARY OF INVENTION

The present disclosure provides an etching solution, an annexing agent, and a manufacturing method of metal wiring. The etching solution does not contain fluorides, is environmentally friendly, and has advantages such as appropriate etching rates, appropriate etching angles, small line width loss, no metal residue, etc.

On first aspect, an embodiment of the present disclosure provides an etching solution. A main ingredient of the etching solution includes hydrogen peroxide accounting for 5% to 30% of a total weight of the etching solution, a hydrogen peroxide stabilizer accounting for 0.1% to 5% of the total weight of the etching solution, a chelant accounting for 5% to 25% of the total weight of the etching solution, a surface active agent accounting for 0.1% to 1% of the total weight of the etching solution, an inorganic acid oxidant accounting for 0.1% to 5% of the total weight of the etching solution, and a remainder of the etching solution is deionized water.

In the etching solution provided by an embodiment of the present disclosure, the hydrogen peroxide stabilizer includes at least one of phenylthiocarbamide, polyacrylamide, or inorganic salt.

In the etching solution provided by an embodiment of the present disclosure, the chelant includes at least one of citric acid, tartaric acid, malonic acid, benzoic acid, diglycolic acid, maleic acid, hydroxyisobutyric acid, nancic acid, malic acid, succinic acid, iso-propanol amine, or propanediol.

In the etching solution provided by an embodiment of the present disclosure, the surface active agent is an alcohol-amine substance, and the alcohol-amine substance includes any one or two selected from a group consisting of poly(ethylene glycol) and polyacrylamide.

In the etching solution provided by an embodiment of the present disclosure, the inorganic acid oxidant includes at least one of nitric acid, phosphoric acid, hydrochloric acid, or sulfuric acid.

On second aspect, an embodiment of the present disclosure further provides an annexing agent, which is added to the etching solution as mentioned above when the etching solution is used repeatedly. A main ingredient of the annexing agent includes an organic acid accounting for 5% to 20% of a total weight of the annexing agent, an etching inhibitor accounting for 0.3% to 3% of the total weight of the annexing agent, and a remainder of the annexing agent is deionized water.

Furthermore, the organic acid includes at least one of citric acid, malonic acid, malic acid, or succinic acid. The etching inhibitor is a benzazole compound.

In the annexing agent provided by an embodiment of the present disclosure, the hydrogen peroxide stabilizer includes at least one of phenylthiocarbamide, polyacrylamide, or inorganic salt.

In the annexing agent provided by an embodiment of the present disclosure, the chelant includes at least one of citric acid, tartaric acid, malonic acid, benzoic acid, diglycolic acid, maleic acid, hydroxyisobutyric acid, nancic acid, malic acid, succinic acid, iso-propanol amine, or propanediol.

In the annexing agent provided by an embodiment of the present disclosure, the surface active agent is an alcohol-amine substance, and the alcohol-amine substance includes any one or two selected from a group consisting of poly(ethylene glycol) and polyacrylamide.

In the annexing agent provided by an embodiment of the present disclosure, the inorganic acid oxidant includes at least one of nitric acid, phosphoric acid, hydrochloric acid, or sulfuric acid.

On third aspect, an embodiment of the present disclosure further provides a manufacturing method of a metal wiring, including following steps:

providing a substrate having a metal layer;

disposing an anti-etching coating layer on a lateral section of the metal layer away from the substrate; and

using the etching solution mentioned above to etch a section of the metal layer not covered by the anti-etching coating layer to form the metal wiring.

In the manufacturing method of the metal wiring provided by an embodiment of the present disclosure, the etched metal layer exists in the etching solution in a form of metal ions; and

the manufacturing method further includes following steps:

detecting a concentration of the metal ions in the etching solution;

wherein when the concentration of the metal ions is over a preset concentration, adding an annexing agent to the etching solution containing the metal ions to allow the etching solution to be used repeatedly; and

wherein a main ingredient of the annexing agent comprises an organic acid accounting for 5% to 20% of a total weight of the annexing agent, an etching inhibitor accounting for 0.3% to 3% of the total weight of the annexing agent, and a remainder of the annexing agent is deionized water.

In the manufacturing method of the metal wiring provided by an embodiment of the present disclosure, the organic acid includes at least one of citric acid, malonic acid, malic acid, or succinic acid.

In the manufacturing method of the metal wiring provided by an embodiment of the present disclosure, the etching inhibitor is a benzazole compound.

In the manufacturing method of the metal wiring provided by an embodiment of the present disclosure, adding the annexing agent to the etching solution containing the metal ions includes following step:

each time the concentration of the metal ions in the etching solution is increased by 1000 ppm, adding the annexing agent accounting for 0.1% to 2% of a total weight of the etching solution into the etching solution containing the metal ions.

In the manufacturing method of the metal wiring provided by an embodiment of the present disclosure, the metal layer includes a metal layer of copper or a copper/molybdenum metal layer.

In the manufacturing method of the metal wiring provided by an embodiment of the present disclosure, the hydrogen peroxide stabilizer includes at least one of phenylthiocarbamide, polyacrylamide, or inorganic salt.

In the manufacturing method of the metal wiring provided by an embodiment of the present disclosure, the chelant includes at least one of citric acid, tartaric acid, malonic acid, benzoic acid, diglycolic acid, maleic acid, hydroxyisobutyric acid, nancic acid, malic acid, succinic acid, iso-propanol amine, or propanediol.

In the manufacturing method of the metal wiring provided by an embodiment of the present disclosure, the surface active agent is an alcohol-amine substance, and the alcohol-amine substance includes any one or two selected from a group consisting of poly(ethylene glycol) and polyacrylamide.

In the manufacturing method of the metal wiring provided by an embodiment of the present disclosure, the inorganic acid oxidant includes at least one of nitric acid, phosphoric acid, hydrochloric acid, or sulfuric acid.

The etching solution provided by the embodiments of the present disclosure does not contain fluorides, and when the metal layers (copper/molybdenum film layers) are etched, the etching solution has advantages such as appropriate etching rates, appropriate etching angles, small line width loss, no metal residue, etc., making it conducive to improving quality of products and lowering processing cost of liquid waste, as well as environmentally friendly. In addition, the annexing agent provided by the embodiments of the present disclosure, which is added to the etching solution during a process of repeatedly using the etching solution, can greatly improve service life of the etching solution, and greatly reduces production cost while substantially decreasing harm to operators and greatly lowering processing cost of etching liquid waste, thereby satisfying requirements from production lines of industries.

### DESCRIPTION OF DRAWINGS

The technical solutions and other advantageous effects of the present invention will be apparent with reference to the following accompanying drawings and detailed description of embodiments of the present disclosure.

FIG. 1 is a scanning electron microscope image of copper/molybdenum wiring obtained from etching a copper/molybdenum film layer by using an etching solution provided by an embodiment of the present disclosure.

FIG. 2 is another scanning electron microscope image of copper/molybdenum wiring obtained from etching the copper/molybdenum film layer by using the etching solution provided by an embodiment of the present disclosure.

FIG. 3 is a scanning electron microscope image of copper/molybdenum wiring obtained from etching the copper/molybdenum film layer by using the etching solution containing copper ions of 500 ppm provided by an embodiment of the present disclosure.

FIG. 4 is a scanning electron microscope image of copper/molybdenum wiring obtained from etching the copper/molybdenum film layer by using the etching solution containing copper ions of 6000 ppm provided by an embodiment of the present disclosure.

FIG. 5 is a scanning electron microscope image of copper/molybdenum wiring obtained from etching the copper/molybdenum film layer after adding an annexing agent to the etching solution containing copper ions of 6000 ppm provided by an embodiment of the present disclosure.

FIG. 6 is a flowchart of a manufacturing method of a metal wiring provided by an embodiment of the present disclosure.

### DETAILED DESCRIPTION OF PREFERRED EMBODIMENTS

The technical solutions in the embodiments of the present disclosure are clearly and completely described in the following with reference to the accompanying drawings in the embodiments of the present disclosure. Obviously, the described embodiments are only part of the embodiments of the present disclosure, but are not all embodiments of the present disclosure. All other embodiments obtained from those skilled in the art based on the embodiments of the present disclosure without creative efforts are within the scope of the present disclosure.

An embodiment of the present disclosure provides an etching solution not containing fluorides for use in etching copper/molybdenum film layers. A main ingredient of the etching solution used to etch copper/molybdenum film layers includes hydrogen peroxide (perhydrol) accounting for 5% to 30% of a total weight of the etching solution, a hydrogen peroxide stabilizer accounting for 0.1% to 5% of the total weight of the etching solution, a chelant accounting for 5% to 25% of the total weight of the etching solution, a surface active agent accounting for 0.1% to 1% of the total weight of the etching solution, an inorganic acid oxidant accounting for 0.1% to 5% of the total weight of the etching solution, and remainder of the etching solution is deionized water. The etching solution provided by this embodiment does not contain an environmentally-damaging azole-type etching inhibitor.

Specifically, a copper/molybdenum film layer is a laminated layer formed from a copper layer (copper or copper alloy) and a molybdenum layer.

Specifically, the hydrogen peroxide is a main oxidant for copper and molybdenum. The hydrogen peroxide stabilizer includes at least one of phenylthiocarbamide, polyacrylamide, or inorganic salt. The appropriate hydrogen peroxide stabilizer can prevent intense chain reactions of the hydrogen peroxide in the etching solution, and can prevent the hydrogen peroxide from decomposing too quickly and generating oxygen ions and hydrogen ions, thereby making the hydrogen peroxide work smoothly and fully to play a role, which is conducive to ensuring an appropriate etching rate and improving etching service life.

Specifically, the chelant includes at least one of citric acid, tartaric acid, malonic acid, benzoic acid, diglycolic acid, maleic acid, hydroxyisobutyric acid, nancic acid, malic acid, succinic acid, iso-propanol amine, or propanediol. The chelant can effectively regulate the etching rate of the etching solution to chelate the copper/molybdenum ions, which is conducive to etching of copper and molybdenum and is conducive to removing residue of molybdenum to obtain a good wiring sectional shape.

Specifically, the surface active agent is an alcohol-amine substance. The alcohol-amine substance includes any one or two selected from a group consisting of poly(ethylene glycol) and polyacrylamide. The surface active agent can make an etching interface be active, which is conducive to performing etching, and is unlikely to cause residues.

Specifically, the inorganic acid oxidant includes at least one of nitric acid, phosphoric acid, hydrochloric acid, or sulfuric acid. The inorganic acid oxidants can play a role in oxidizing metals and effects of chelating and dissolving, which is conducive to complete elimination of metal substances and is unlikely to cause residues.

Specifically, a configuration method of the etching solution provided by an embodiment of the present disclosure is sequentially adding quantitative water, hydrogen peroxide, chelant, hydrogen peroxide stabilizer, inorganic acid oxidant, and surface active agent into a container, and stirring for 60 minutes to 180 minutes until evenly mixed, and in the process of the configuration mentioned above, a temperature should be controlled at 15° C. to 30° C. In an embodiment, in the etching solution, a mass fraction of the hydrogen peroxide (perhydrol) is 7.8%, a mass fraction of the hydrogen peroxide stabilizer is 0.1%, a mass fraction of the chelant is 16%, a mass fraction of the surface active agent is 0.1%, a mass fraction of the inorganic acid oxidant is 2.2%, and a mass fraction of the deionized water is 73.8%.

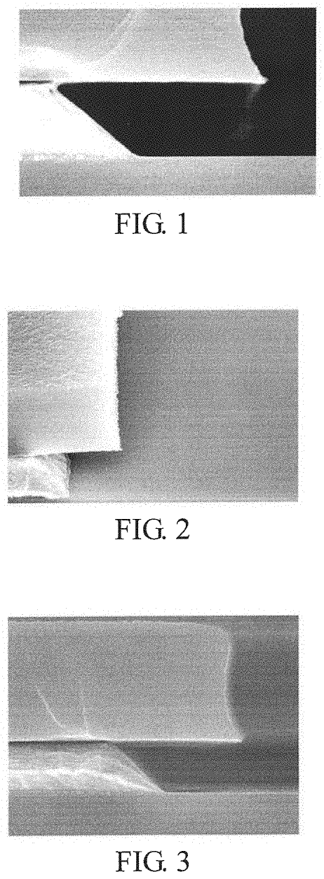

FIG. 1 is a scanning electron microscope image of copper/molybdenum wiring obtained from etching a copper/molybdenum film layer by using an etching solution provided by an embodiment of the present disclosure, and it is a lateral view scanning electron microscope image, specifically. In the figure, from top to bottom are sequentially a substrate glass, the copper/molybdenum wiring, and an anti-etching coating layer. From FIG. 1, it can be understood that when using the etching solution of the embodiments of the present disclosure to perform etching, an appropriate etching angle ranges from 30 degrees to 50 degrees. FIG. 2 is a scanning electron microscope image with a top view at around 30 degrees viewing angle of copper/molybdenum wiring obtained from etching a copper/molybdenum film layer by using the etching solution provided by an embodiment of the present disclosure. Each of the film layers in FIG. 2 is same as each of the film layers in FIG. 1, only the viewing angle is different. From FIG. 2, it can be understood that there is no metal residue on a section not covered by the anti-etching coating layer.

The etching solution provided by this embodiment does not contain fluorides. When the etching solution etches the copper/molybdenum film layer, the etching rate is appropriate, so this is unlikely to damage the substrate glass, and further has advantages such as appropriate etching angles (tapers) ranging from 30 degrees to 50 degrees, small line width loss (critical dimension loss, CD loss), no metal residue, etc. Moreover, it is environmentally friendly, and is conducive to lowering processing cost of liquid waste.

During the process of using the etching solution of the copper/molybdenum film layer repeatedly (that is, using the etching solution cyclically to perform etching, wherein the etched copper exists in the etching solution in a form of copper ions during the etching process), a concentration of the copper ions in the etching solution is large, for example, 4000 ppm to 6000 ppm, wherein ppm is parts per million. Due to decomposition of the hydrogen peroxide and insufficiency of the chelant (the chelant of copper ions), a pH value of the solution is increased, easily leading to poor etching performance at this time, for example, etching too slowly, residues of the molybdenum layer, nonstandard etching angles, etc., which greatly increases cost during use in industrial production. For example, when the concentration of the copper ions of the etching solution provided by the embodiments of the present disclosure is less than 6000 ppm, the etching solution can satisfy the use in production lines, and when the concentration of the copper ions is greater than 6000 ppm, if the etching is continuously carried out, the problems such as excessively slow etching rates, poor etching angles, residues of the molybdenum layer, etc. can occur. In order to solve the problems mentioned above, the present disclosure further provides an annexing agent,

Specifically, an embodiment of the present disclosure further provides an annexing agent. When the etching solution mentioned above is used repeatedly, the annexing agent is added to the etching solution, which can correct problems such as etching rates, etching angles, metal residue, etc. of the etching solution in a high concentration of copper ions. A main ingredient of the annexing agent includes an organic acid accounting for 5% to 20% of a total weight of the annexing agent, an etching inhibitor accounting for 0.3% to 3% of the total weight of the annexing agent, and remainder of the annexing agent is deionized water. Furthermore, the organic acid includes at least one of citric acid, maionic acid, malic acid, or succinic acid. The etching inhibitor is a benzazole compound.

Specifically, a configuration of the annexing agent provided by an embodiment of the present disclosure is sequentially adding quantitative water, inorganic acid oxidant, and etching inhibitor into a container, and stirring for 60 minutes to 180 minutes until evenly mixed, and in the process of the configuration mentioned above, a temperature should be controlled at 15° C. to 30° C. In an embodiment, in the annexing agent, a mass fraction of the organic acid is 8%, a mass fraction of the etching inhibitor is 0.6%, and a mass fraction of the deionized water is 91.4%.

Specifically, when the concentration of the copper ions in the etching solution exceeds a preset concentration, adding the annexing agent into the etching solution. The adding approach is each time the concentration of the metal ions in the etching solution is increased by 1000 ppm, adding the annexing agent accounting for 0.1% to 2% of a total weight of the etching solution into the etching solution containing the copper ions. Furthermore, the preset concentration is less than or equal to 6000 ppm, can be 4000 ppm, and can be 6000 ppm or other values, which is set according to actual situations. It should be noted that the adding approach of the annexing agent can be adjusted according to actual production situations, for example, when the concentration of the copper is increased by 500 ppm, adding the annexing agent once, and it is not limited herein.

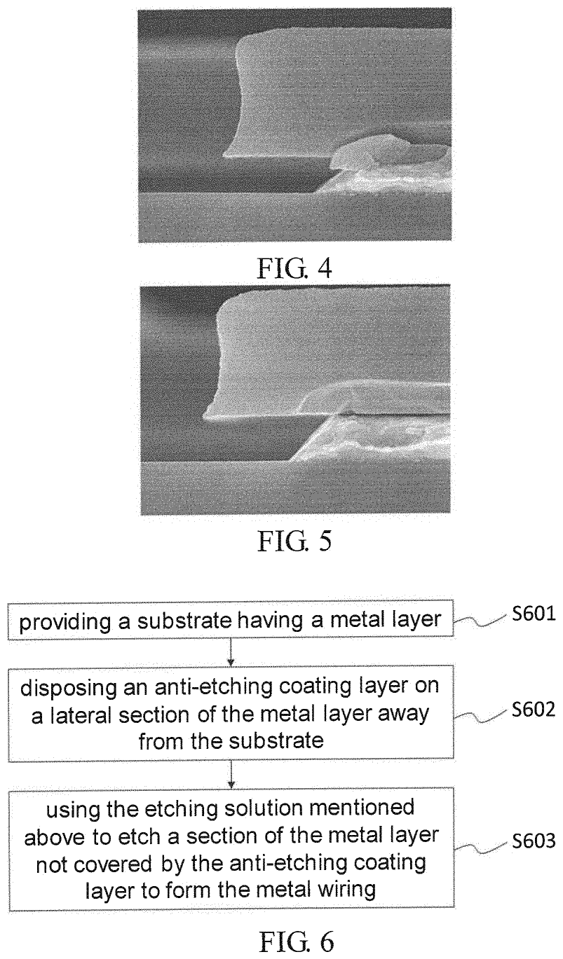

Specifically, in order to review the effect of the etching solution and the annexing agent provided by the embodiments of the present disclosure, the etching solution containing copper ions of 500 ppm, the etching solution containing copper ions of 6000 ppm, and the etching solution containing copper ions of 6000 ppm after adding the annexing agent are used in the present disclosure to perform etching on same copper/molybdenum layers in a same time section in a situation that other conditions are same, and wherein, an etching temperature is 35° C., and a pH value of the etching solution is 4.4. After the etching, using a scanning electron microscope to observe etching features of the copper/molybdenum film layers, and results are shown in FIG. 3, FIG, 4, and FIG. 5. FIG. 3 is a scanning electron microscope image of copper/molybdenum wiring obtained from etching the copper/molybdenum film layer by using the etching solution containing copper ions of 500 ppm. FIG. 4 is a scanning electron microscope image of copper/molybdenum wiring obtained from etching the copper/molybdenum film layer by using the etching solution containing copper ions of 6000 ppm. FIG. 5 is a scanning electron microscope image of copper/molybdenum wiring obtained from etching the copper/molybdenum film layer after adding the annexing agent to the etching solution containing copper ions of 6000 ppm.

Furthermore, the etching angles of the copper/molybdenum wiring in the FIG. 3, FIG. 4, and FIG. 5 are respectively 48°31′, 25°59′, and 46°36′. From FIG. 3 and FIG. 4, it can be understood that when the concentration of the copper ions in the etching solution is increased, the etching angles are greatly decreased. From FIG. 3 to FIG. 5, it can be understood that after the annexing agent is added, the etching angles can be corrected, and the difference compared to the etching angles of the etching solution containing the copper ions of 500 ppm is small. Furthermore, line width losses on one side of the copper/molybdenum wiring are respectively 1456 nm, 1066 nm, and 1419 nm. From FIG. 3 and FIG. 4, it can be understood that after the concentration of the copper ions in the etching solution is increased, the line width losses on one side are decreased, which makes the differences between the line widths obtained from etching large. From FIG. 3 to FIG. 5, it can be understood that after the annexing agent is added, the line width losses on one side can be corrected, and the difference compared to the loss of the line widths of the etching solution containing the copper ions of 500 ppm is small. In addition, because FIG. 3, FIG. 4, and FIG. 5 are effect diagrams of etching in the same time section, the etching rates can be reviewed from the line width losses on one side. From FIG. 3 and FIG. 4, it can be understood that after the concentrations of the copper ions in the etching solutions are increased, the etching rates are decreased, and from FIG. 3 and FIG. 5, after the annexing agent is added, the etching rates can be recovered to the level in FIG. 3. Therefore, the annexing agent provided by the present disclosure can effectively correct the etching characteristics of the etching solutions.

In this embodiment, adding the annexing agent provided by this embodiment during the process of using the etching solution repeatedly allows the etching characteristics to be corrected. That is, the etching rate can be ensured to be stable and appropriate, the etching angle can be ensured to be stable at 30 degrees to 50 degrees, and the line width loss can be ensured to be small and stable, which makes the difference in the formed metal wiring small. In addition, adding the annexing agent makes service life of the etching solution to be more than 12000 ppm (the concentration of the copper ions in the etching solution), which greatly improves service life of the etching solution, thereby greatly reducing usage amount of a new etching solution and a liquid waste amount of the generated etching solution, and greatly lowers production cost while substantially reducing harm to operators and greatly lowering processing cost of etching liquid waste, thereby satisfying requirements from production lines of industries.

As illustrated in FIG. 6, an embodiment of the present disclosure further provides a manufacturing method of metal wiring, specifically the manufacturing of copper/molybdenum wiring, which includes following steps:

step 3601: providing a substrate having a metal layer;

Specifically, a material of the substrate includes glass, and the metal layer includes a metal layer of copper or a copper/molybdenum metal layer.

step S602: disposing an anti-etching coating layer on a lateral section of the metal layer away from the substrate.

Specifically, a material of the anti-etching coating layer includes a photoresist material, and it is not limited herein.

step S603: using the etching solution mentioned above to etch a section of the metal layer not covered by the anti-etching coating layer to form the metal wiring.

Specifically, an ingredient of the etching solution includes hydrogen peroxide (perhydrol) accounting for 7.8% of a total weight of the etching solution, a hydrogen peroxide stabilizer accounting for 0.1% of the total weight of the etching solution, a chelant accounting for 16% of the total weight of the etching solution, a surface active agent accounting for 0.1% of the total weight of the etching solution, an inorganic acid oxidant accounting for 2.2% of the total weight of the etching solution, and deionized water accounting for 73.8% of the total weight of the etching solution. An etching temperature is 35° C., and a pH value of the etching solution is 4.4.

In an embodiment, the etched metal layer exists in the etching solution in a form of metal ions, and the manufacturing method of the metal wiring further includes following steps:

detecting a concentration of the metal ions (copper ions) in the etching solution; when the concentration of the metal ions is over a preset concentration, adding an annexing agent to the etching solution containing the metal ions to make the etching solution be used repeatedly. Furthermore, a main ingredient of the annexing agent includes an organic acid accounting for 5% to 20% of a total weight of the annexing agent, an etching inhibitor accounting for 0.3% to 3% of the total weight of the annexing agent, and remainder of the annexing agent is deionized water. Furthermore, the organic acid includes at least one of citric acid, malonic acid, malic acid, or succinic acid. The etching inhibitor is a benzazole compound.

Specifically, the preset concentration is less than or equal to 6000 ppm, can be 4000 ppm, and can be 6000 ppm or other values, which is set according to actual situations.

Specifically, the ingredient of the annexing agent includes the organic acid accounting for 8% of the total weight of the annexing agent, the etching inhibitor accounting for 0.6% of the total weight of the annexing agent, and the deionized water accounting for 91.4% of the total weight of the annexing agent.

Specifically, adding the annexing agent containing metal ions to the etching solution includes following step:

Each time the concentration of the metal ions in the etching solution is increased by 1000 ppm, adding the annexing agent accounting for 0.1% to 2% of a total weight of the etching solution into the etching solution containing the metal ions. Of course, the adding approach of the annexing agent can be adjusted according to actual production situations, for example, each time the concentration of the copper is increased by 500 ppm, adding the annexing agent once, and it is not limited herein,

In this embodiment, when using the etching solution and the annexing agent of the embodiments mentioned above to manufacture the metal wiring, the etching rate can be stable and appropriate, the etching angle is stable at 30 degrees to 50 degrees, the line width loss is small and stable, and there is no metal residue, which are conducive to improving product quality. In addition, adding the annexing agent can greatly improve service life of the etching solution, thereby greatly reducing usage amount of a new etching solution and a liquid waste amount of the generated etching solution, and greatly lowers production cost while substantially lowering harm to operators and greatly reducing processing cost of etching liquid waste, thereby satisfying requirements from production lines of industries.

In the embodiments mentioned above, the descriptions to the various embodiments are emphasized, and the part is not described in detailed in an embodiment, can refer to the detailed description of other embodiments mentioned above.

The etching solution, the annexing agent, and the manufacturing method of the metal wiring provided by the embodiments of the present disclosure are described in detail above. This article uses specific cases for describing the principles and the embodiments of the present disclosure, and the description of the embodiments mentioned above is only for helping to understand the method and the core idea of the present disclosure. It should be understood by those skilled in the art, that it can perform changes in the technical solution of the embodiments mentioned above, or can perform equivalent replacements in part of technical characteristics, and the changes or replacements do not make the essence of the corresponding technical solution depart from the scope of the technical solution of each embodiment of the present disclosure.

What is claimed is:

1. An etching solution, wherein a main ingredient of the etching solution comprises hydrogen peroxide accounting for 5% to 30% of a total weight of the etching solution, a hydrogen peroxide stabilizer accounting for 0.1% to 5% of the total weight of the etching solution, a chelant accounting for 5% to 25% of the total weight of the etching solution, a surface active agent accounting for 0.1% to 1% of the total weight of the etching solution, an inorganic acid oxidant accounting for 0.1% to 5% of the total weight of the etching solution, and a remainder of the etching solution is deionized water.

2. The etching solution as claimed in claim 1, wherein the hydrogen peroxide stabilizer comprises at least one of phenylthiocarbamide, polyacrylamide, or inorganic salt.

3. The etching solution as claimed in claim 1, wherein the chelant comprises at least one of citric acid, tartaric acid, malonic acid, benzoic acid, diglycolic acid, maleic acid, hydroxyisobutyric acid, nancic acid, malic acid, succinic acid, iso-propanol amine, or propanediol.

4. The etching solution as claimed in claim 1, wherein the surface active agent is an alcohol-amine substance, and the alcohol-amine substance comprises any one or two selected from a group consisting of poly(ethylene glycol) and polyacrylamide.

5. The etching solution as claimed in claim 1, wherein the inorganic acid oxidant comprises at least one of nitric acid, phosphoric acid, hydrochloric acid, or sulfuric acid.

6. An annexing agent, which is added to the etching solution as claimed in claim 1 when the etching solution is used repeatedly, wherein a main ingredient of the annexing agent comprises an organic acid accounting for 5% to 20% of a total weight of the annexing agent, an etching inhibitor accounting for 0.3% to 3% of the total weight of the annexing agent, and a remainder of the annexing agent is deionized water; and
wherein the organic acid comprises at least one of citric acid, malonic acid, malic acid, or succinic acid, and the etching inhibitor is a benzazole compound.

7. The annexing agent as claimed in claim 6, wherein the hydrogen peroxide stabilizer comprises at least one of phenylthiocarbamide, polyacrylamide, or inorganic salt.

8. The annexing agent as claimed in claim 6, wherein the chelant comprises at least one of citric acid, tartaric acid, malonic acid, benzoic acid, diglycolic acid, maleic acid, hydroxyisobutyric acid, nancic acid, malic acid, succinic acid, iso-propanol amine, or propanediol.

9. The annexing agent as claimed in claim 6, wherein the surface active agent is an alcohol-amine substance, and the alcohol-amine substance comprises any one or two selected from a group consisting of poly(ethylene glycol) and polyacrylamide.

10. The annexing agent as claimed in claim 6, wherein the inorganic acid oxidant comprises at least one of nitric acid, phosphoric acid, hydrochloric acid, or sulfuric acid.

11. A manufacturing method of a metal wiring, comprising following steps:
providing a substrate having a metal layer;
disposing an anti-etching coating layer on a lateral section of the metal layer away from the substrate; and
using the etching solution as claimed in claim 1 to etch a section of the metal layer not covered by the anti-etching coating layer to form the metal wiring.

12. The manufacturing method of the metal wiring as claimed in claim 11, wherein the etched metal layer exists in the etching solution in a form of metal ions; and
the manufacturing method comprises following steps:
detecting a concentration of the metal ions in the etching solution;
wherein when the concentration of the metal ions is over a preset concentration, adding an annexing agent to the etching solution containing the metal ions to allow the etching solution to be used repeatedly; and
wherein a main ingredient of the annexing agent comprises an organic acid accounting for 5% to 20% of a total weight of the annexing agent, an etching inhibitor accounting for 0.3% to 3% of the total weight of the annexing agent, and a remainder of the annexing agent is deionized water.

13. The manufacturing method of the metal wiring as claimed in claim 12, wherein the organic acid comprises at least one of citric acid, malonic acid, malic acid, or succinic acid.

14. The manufacturing method of the metal wiring as claimed in claim 12, wherein the etching inhibitor is a benzazole compound.

15. The manufacturing method as claimed in claim 12, wherein adding the annexing agent to the etching solution containing the metal ions comprises following step:
each time the concentration of the metal ions in the etching solution is increased by 1000 ppm, adding the annexing agent accounting for 0.1% to 2% of a total weight of the etching solution to the etching solution containing the metal ions.

16. The manufacturing method of the metal wiring as claimed in claim 11, wherein the metal layer comprises a metal layer of copper or a copper/molybdenum metal layer.

17. The manufacturing method of the metal wiring as claimed in claim 11, wherein the hydrogen peroxide stabilizer comprises at least one of phenylthiocarbamide, polyacrylamide, or inorganic salt.

18. The manufacturing method of the metal wiring as claimed in claim 11, wherein the chelant includes at least one of citric acid, tartaric acid, malonic acid, benzoic acid, din/colic acid, maleic acid, hydroxyisobutyric acid, nancic acid, malic acid, succinic acid, iso-propanol amine, or propanediol.

19. The manufacturing method of the metal wiring as claimed in claim 11, wherein the surface active agent is an alcohol-amine substance, and the alcohol-amine substance comprises any one or two selected from a group consisting of poly(ethylene glycol) and polyacrylamide.

20. The manufacturing method of the metal wiring as claimed in claim 11, wherein the inorganic acid oxidant comprises at least one of nitric acid, phosphoric acid, hydrochloric acid, or sulfuric acid.
